(19) United States
(12) Patent Application Publication
(10) Pub. No.: US 2015/0179843 A1
(43) Pub. Date: Jun. 25, 2015

(54) PHOTOVOLTAIC DEVICE

(71) Applicant: Panasonic Corporation, Osaka (JP)

(72) Inventor: DAIJI KANEMATSU, FUKUSHIMA (JP)

(21) Appl. No.: 14/641,181

(22) Filed: Mar. 6, 2015

Related U.S. Application Data
(63) Continuation of application No. PCT/JP2014/003190, filed on Jun. 16, 2014.

(30) Foreign Application Priority Data
Aug. 1, 2013 (JP) 2013-160338

(51) Int. Cl. H01L 31/0352

(52) U.S. Cl. CPC H01L 31/035218; Y10S 977/814; B82Y 20/00

(57) ABSTRACT

A photovoltaic device includes a photovoltaic portion having light-receiving surface that receives light, the photovoltaic portion including a nano-structure. the nano-structure includes one or more first regions and one or more second regions. In each of the one or more first regions, semiconductor layer portions are arranged at a first density, and in each of the one or more second regions, at least one semiconductor layer portion is arranged at a second density lower than the first density. The nano-structure includes an insulator having a refractive index lower than that of the semiconductor layer portions arranged in the one or more first regions and the one or more second regions.

### BACKGROUND

1. Technical Field

The present disclosure relates to a photovoltaic device.

2. Description of the Related Art

In recent years, photovoltaic devices, also called solar batteries, which convert inexhaustible solar energy into electric energy have been enthusiastically developed. Such photovoltaic devices are broadly classified into silicon-based photovoltaic devices, compound semiconductor-based photovoltaic devices, inorganic material-based photovoltaic devices, and dye sensitizer-based photovoltaic devices in terms of materials that generate a photoelectromotive force. Among them, silicon-based photovoltaic devices constitute mainstream global production. In particular, photovoltaic elements having a high conversion efficiency of 20% or more are realized in crystalline silicon-based photovoltaic devices composed of a monocrystalline or polycrystalline silicon wafer serving as a photoelectromotive material. However, the conversion efficiency of crystalline silicon-based photovoltaic devices at present is dependent on the forbidden band width of crystalline silicon. To achieve a conversion efficiency of 30% or more, the forbidden band width needs to be controlled.

For example, it is known that when the size of particles of a semiconductor material is decreased to a size equal to or smaller than the de Broglie wavelength (about 10 nm), the forbidden band width is increased due to a quantum size effect. This provides a method for controlling the forbidden band width of silicon by fabricating a photovoltaic device including a silicon nano-structure having a diameter of 10 nm or less.

In photovoltaic devices including a silicon nano-structure as an electromotive force generator, the silicon density decreases and thus the transmission loss of light increases, which may decrease the amount of electric power generated. However, there has been proposed a technique of absorbing a sufficient amount of light by increasing the density of a nano-structure (refer to Japanese Unexamined Patent Application Publication No. 2012-182389).

### SUMMARY

One non-limiting and exemplary embodiment provides a technique of improving the conversion efficiency (i.e. generation efficiency) in a photovoltaic device having a photovoltaic portion including a nano-structure.

A photovoltaic device according to an embodiment of the present disclosure includes a photovoltaic portion having light-receiving surface that receives light, the photovoltaic portion including a nano-structure. the nano-structure includes one or more first regions and one or more second regions. In each of the one or more first regions, semiconductor layer portions are arranged at a first density, and in each of the one or more second regions, at least one semiconductor layer portion is arranged at a second density lower than the first density. The nano-structure includes an insulator having a refractive index lower than that of the semiconductor layer portions arranged in the one or more first regions and the one or more second regions.

It should be noted that general or specific embodiments may be implemented as an element, device, apparatus, system, a method, or any selective combination thereof.

According to the present disclosure, the conversion efficiency (i.e. generation efficiency) in a photovoltaic device having a photovoltaic portion including a nano-structure can be improved. Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a sectional view illustrating a structure of a photovoltaic device according to this embodiment;

FIG. 2 is a sectional view illustrating a method for producing the photovoltaic device according to this embodiment;

FIG. 3 is a sectional view illustrating a method for producing the photovoltaic device according to this embodiment;

FIG. 4 is a sectional view illustrating a method for producing the photovoltaic device according to this embodiment;

FIG. 5 is a sectional view illustrating a method for producing the photovoltaic device according to this embodiment;

FIG. 6 is a sectional view illustrating a method for producing the photovoltaic device according to this embodiment;

FIG. 7 is a sectional view illustrating a method for producing the photovoltaic device according to this embodiment;

FIG. 8 shows the calculation result of the light absorption amount of a photovoltaic device according to one aspect of this embodiment;

FIG. 9 is a top view illustrating a nano-structure of the photovoltaic device according to this embodiment;

FIG. 10 is a top view illustrating a nano-structure of a photovoltaic device according to a modification of this embodiment; and

FIG. 11 is a top view illustrating a nano-structure of a photovoltaic device according to another modification of this embodiment.

### DETAILED DESCRIPTION

The present inventor has found that when a nano-structure is densely formed, the refractive index gap on the light incident side increases and an effect of reducing the surface reflection loss is not sufficiently produced. The present disclosure is based on this finding and provides a technique of improving the conversion efficiency (i.e. generation efficiency) in a photovoltaic device having a photovoltaic portion including a nano-structure.

Hereafter, an embodiment of the present disclosure will be described in detail with reference to the attached drawings. In the description of the drawings, the same elements are designated by the same reference numerals and the description thereof is appropriately omitted to avoid redundancy.

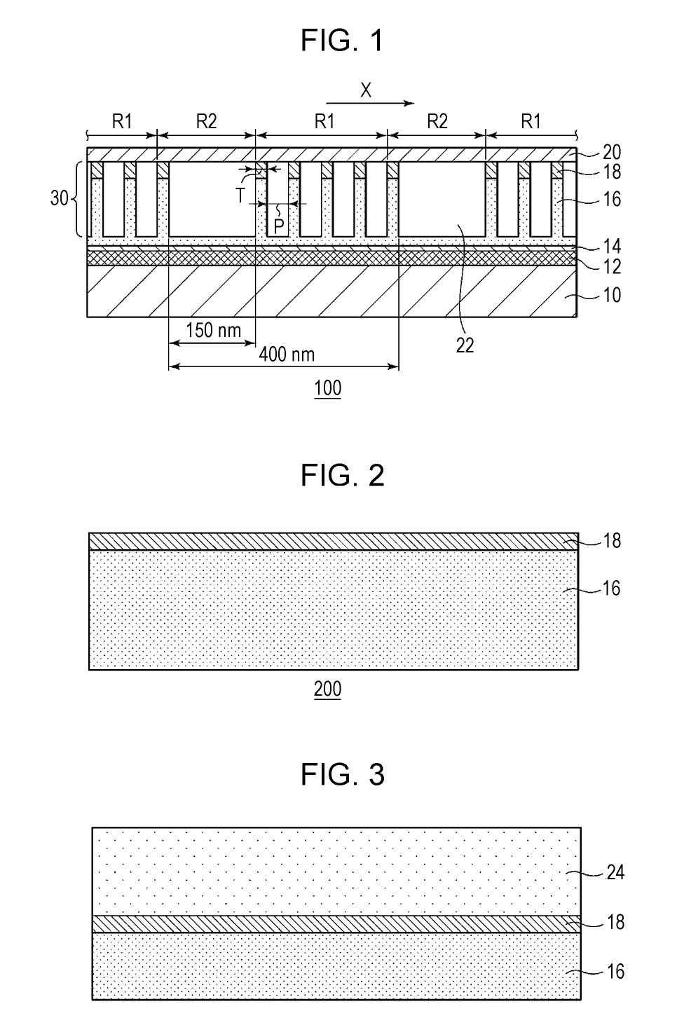

FIG. 1 is a sectional view illustrating a structure of a photovoltaic device according to this embodiment. As illustrated in FIG. 1, a photovoltaic device 100 according to this embodiment includes a first supporting substrate 10, a metal layer 12, a second transparent electrode layer 14, a second conductivity type silicon layer 16, a first conductivity type silicon layer 18, a first transparent electrode layer 20, and a transparent insulator 22. Stacked bodies each including a portion of the second conductivity type silicon layer 16 and the first conductivity type silicon layer 18 constitute a nano-structure 30.

The refractive index of the first transparent electrode layer 20 is about 2. The refractive index of the transparent insulator 22 is 2 or less.

The first supporting substrate 10 has an insulating surface and also has a strength capable of mechanically supporting a photovoltaic element portion including the nano-structure 30. For example, the first supporting substrate 10 is a resin substrate having a thickness of about 1 mm to 5 mm.

The metal layer 12 is made of a conductive material such as a metal. For example, the conductive material is a material containing silver (Ag) or aluminum (Al). The second transparent electrode layer 14 may be made of one or more of transparent conductive oxides (TCOs) obtained by doping tin oxide (SnO₂), zinc oxide (ZnO), indium tin oxide (ITO), and the like with tin (Sn), antimony (Sb), fluorine (F), aluminum (Al), and the like. In particular, zinc oxide (ZnO) has advantages such as a good light transmission property and low resistivity.

One electrode portion connected to the nano-structure 30 is constituted by a stacked structure including the second transparent electrode layer 14 and the metal layer 12. The total thickness of the second transparent electrode layer 14 and the metal layer 12 may be about 1000 nm.

The second conductivity type silicon layer 16 is made of monocrystalline silicon to which a p-type dopant is added. The thickness of the second conductivity type silicon layer 16 is increased to the degree that incident light is sufficiently absorbed, for example, 10 μm. The first conductivity type silicon layer 18 is made of monocrystalline silicon to which an n-type dopant is added. The thickness of the first conductivity type silicon layer 18 is increased to the degree that the open-circuit voltage of the photovoltaic element portion including the nano-structure 30 is sufficiently increased, for example, 400 nm. The refractive indices of the second conductivity type silicon layer 16 and the first conductivity type silicon layer 18 are about 3.6 to 4.

The transparent insulator 22 is disposed so as to fill spaces in the nano-structure 30. The transparent insulator 22 has a light transmission property and takes a role in, for example, terminating dangling bonds on the surfaces of the first conductivity type silicon layer 18 and the second conductivity type monocrystalline silicon layer 16.

The first transparent electrode layer 20 may be made of one or more of transparent conductive oxides (TCOs) obtained by doping tin oxide (SnO₂), zinc oxide (ZnO), indium tin oxide (ITO), and the like with tin (Sn), antimony (Sb), fluorine (F), aluminum (Al), gallium (Ga), and the like. In particular, zinc oxide (ZnO) has advantages such as a good light transmission property and low resistivity.

In this embodiment, a surface on the first transparent electrode layer 20 side of the photovoltaic device 100 serves as a light-receiving surface. The term “light-receiving surface” means a main surface upon which light is mainly incident in the photovoltaic element portion. Specifically, the light-receiving surface is a surface upon which most of light that enters the photovoltaic element portion is incident.

The nano-structure 30 is disposed on the light-receiving surface side (on the upper surface side in FIG. 1) so that nano-walls extend in a direction perpendicular to the light-receiving surface. The width (thickness) of the nano-walls of the nano-structure 30 can be decreased to the degree that an increase in the forbidden band width is caused due to a quantum size effect. Specifically, the width T of the shortest side of the incident surface of each nano-wall may be, for example, 10 nm or less, 6 nm or less, or about 4 nm.

Hereafter, a method for producing the photovoltaic device 100 according to this embodiment will be described with reference to FIGS. 2 to 7.

First, a second conductivity type monocrystalline silicon wafer 200 is prepared. A first conductivity type silicon layer 18 is formed on the one-main-surface side of the second conductivity type monocrystalline silicon wafer 200 (FIG. 2). The first conductivity type silicon layer 18 is formed by exposing the second conductivity type monocrystalline silicon wafer 200 to a phosphorus oxychloride (POCl₃) gas atmosphere in an electric diffusion furnace at 870° C.

A second supporting substrate 24 is bonded to the light-receiving surface side of the first conductivity type silicon layer 18. A second conductivity type silicon layer 16 is formed after polishing a surface second supporting substrate 24, the surface located opposite the light-receiving surface of the second conductivity type monocrystalline silicon wafer 200 (FIG. 3). The second conductivity type silicon layer 16 has, for example, a thickness such that light can be sufficiently absorbed. For example, the thickness may be about 10 μm.

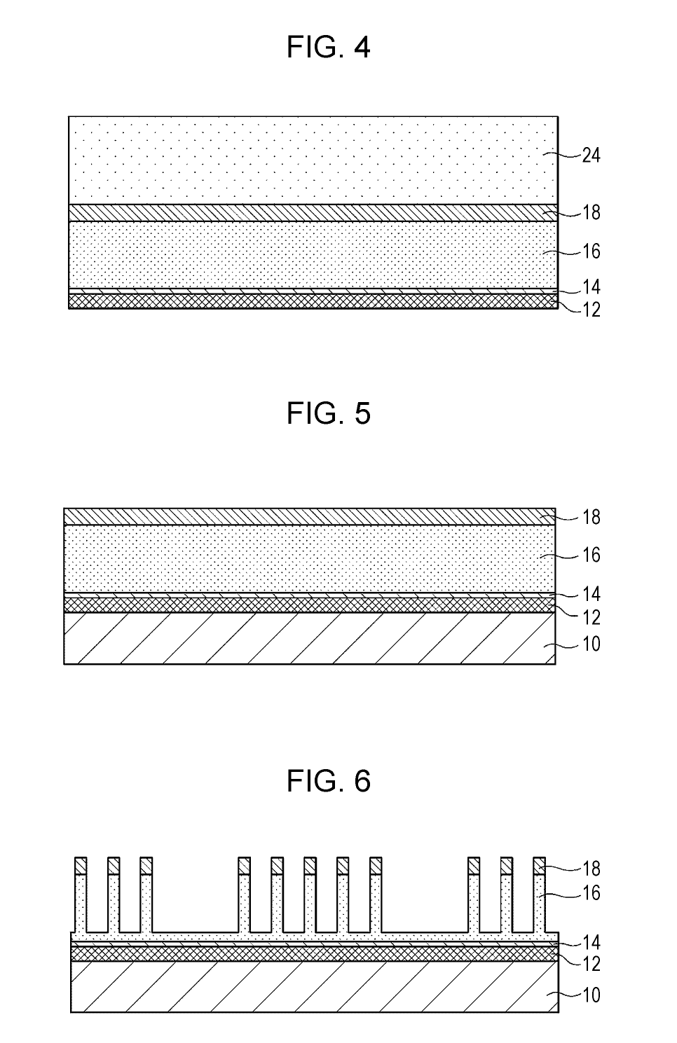

The second transparent electrode layer 14 and the metal layer 12 are formed on the back side of the second conductivity type silicon layer 16 by a sputtering method or the like (FIG. 4). A first supporting substrate 10 is further disposed on the metal layer 12. After the metal layer 12 and the first supporting substrate 10 are bonded to each other with an adhesive, by room temperature bonding, or the like, the second supporting substrate 24 is detached from the first conductivity type silicon layer 18 (FIG. 5).

Portions of the first conductivity type silicon layer 18 and the second conductivity type silicon layer 16 are processed into a wall shape or a wire shape. Thus, a nano-structure 30 is formed. For example, a mask is formed on a surface of a photovoltaic element portion, and a silver film is formed in openings of the mask by a sputtering method or the like. After the mask is removed, dipping in an aqueous HF/H₂O₂ solution is performed. As a result, portions on which the silver film has been formed are selectively etched and thus the nano-structure 30 can be formed.

The mask is formed by applying a resin onto the surface of the photovoltaic element portion and drawing a pattern by electron beam lithography or the like. The shape and arrangement of the nano-structure 30 can be desirably controlled in accordance with the shape of the mask.

For example, when the openings of the mask have a line-and-space pattern having periodicity in a one-dimensional direction, nano-walls can be formed. When the openings have a hole pattern having periodicity in a two-dimensional direction, nano-wires can be formed.

By forming a mask including portions in which the openings are arranged at a high density and portions in which the openings are arranged at a low density, the nano-structure 30 according to this embodiment is formed (FIG. 6). Finally, Ag particles that remain in regions between nano-walls or nano-wires of the nano-structure 30 are removed, for example, by performing dipping in a mixture solution of NH₄OH and H₂O₂ or another solution.

In this embodiment, etching is stopped in a middle portion of the second conductivity type silicon layer 16 so that part of the second conductivity type silicon layer 16 on the surface side is processed into a wall shape or a wire shape. However, the second conductivity type silicon layer 16 may be etched until the surface of the second transparent electrode layer 14 is exposed.

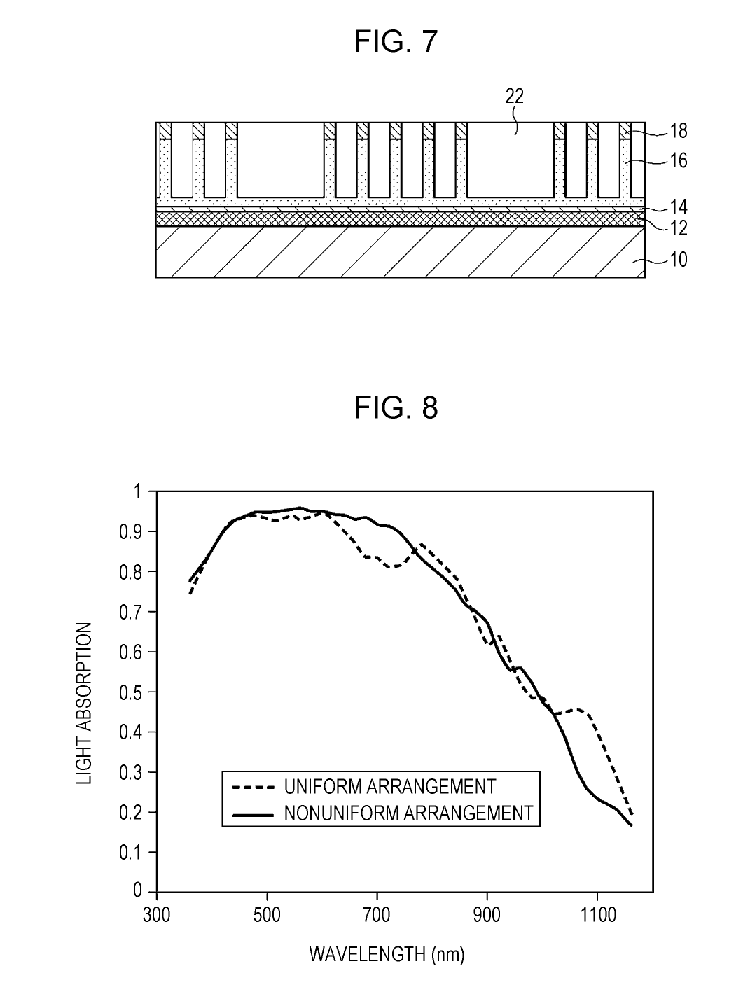

Subsequently, a transparent insulator 22 is formed so as to fill spaces of the nano-structure 30 (FIG. 7). The transparent insulator 22 can be formed by forming an insulating film composed of silicon nitride (SiN), silicon oxide (SiOₓ), or aluminum oxide (Al₁₋ₓOₓ) by atomic layer deposition (ALD) and then removing part of a surface of the insulating film by etching. The etching treatment can be controlled so that at least tips of the nano-structure 30 (i.e. a surface of the first conductivity type silicon layer 18) is exposed. The transparent insulator 22 is made of a material having a refractive index lower than that of the first conductivity type silicon layer 18.

Subsequently, a first transparent electrode layer 20 is formed by a sputtering method or the like so as to cover the first conductivity type silicon layer 18 and the transparent insulator 22 (FIG. 1). Herein, the first transparent electrode layer 20 is formed so as to be connected to the nano-structure 30 (first conductivity type silicon layer 18).

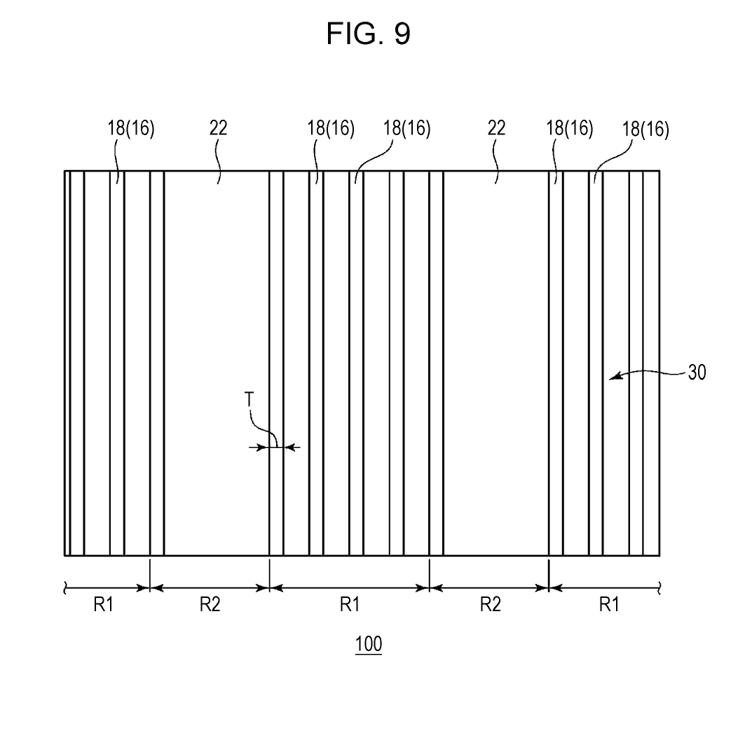

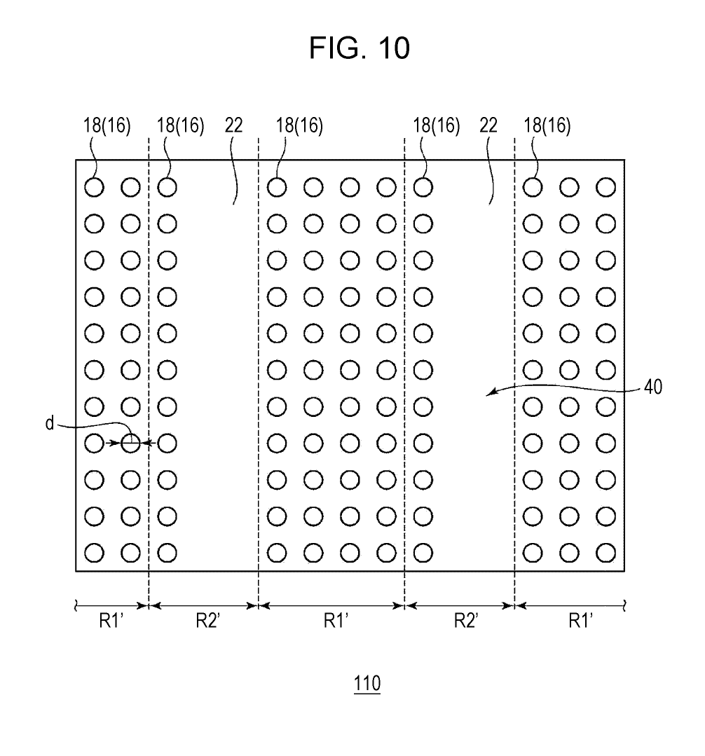

Subsequently, a transparent protective film (not illustrated) is formed on the surface of the first transparent electrode layer 20, if needed. Thus, the photovoltaic device 100 including the nano-structure 30 as a photovoltaic portion is produced. As illustrated in FIG. 1 (and FIG. 9), the nano-structure 30 according to this embodiment includes first regions R1 in which nano-wall-shaped semiconductor layer portions are arranged at a first density (high density) and second regions R2 in which nano-wall-shaped semiconductor layer portions are arranged at a second density (low density) which is different from the first density. Consequently, the transmission loss of light is reduced in the first regions R1 in which the semiconductor layers are arranged at a relatively high density. On the other hand, the reflection loss of light is reduced in the second regions R2 in which the semiconductor layers are arranged at a relatively low density, that is, in the second regions R2 in which the transparent insulator 22 having a refractive index lower than that of the semiconductor layers occupies a large area. Herein, when the width of each first region R1 is larger than the optical path length of one wavelength and the width of each second region R2 is smaller than the optical path length of one wavelength, the incident light is gathered in the first regions R1. As a result, both a low reflection loss and a low transmission loss are achieved, and the conversion efficiency (i.e. generation efficiency) can be improved compared with nano-structure photovoltaic devices of the related art.

In the nano-structure 30, the optimum sizes of the first regions R1 and the second regions R2 may be calculated in consideration of, for example, the size, shape, material, and arrangement density of the semiconductor layers. For example, assuming that the minimum wavelength of sunlight that contributes to power generation is 360 nm, the average refractive index of the first regions R1 is 3, and the average refractive index of the second regions R2 is 2, the size of each first region R1 may be 120 nm or more and the size of each second region R2 may be 180 nm or less.

As illustrated in FIG. 1 (and FIG. 9), in the nano-structure 30, both a lower reflection loss and a lower transmission loss can be achieved by periodically arranging optimum first regions R1 and second regions R2 in at least one direction horizontal to the first supporting substrate 10.

In the nano-wall-shaped semiconductor layer portions, the thickness T of each wall in the arrangement direction X may be 10 nm or less. In the nano-wire-shaped semiconductor layer portions, the diameter d of each wire may be 10 nm or less. Thus, the forbidden band width is increased due to a quantum size effect.

The shape of the nano-wall-shaped semiconductor layer portions in the first regions R1 and the second regions R2 is not particularly limited. For example, the nano-wall-shaped semiconductor layer portions may be intermittently formed in the longitudinal direction. As illustrated in FIG. 9, in the nano-structure 30, the arrangement density of nano-wall-shaped semiconductor layer portions in the longitudinal direction may be constant as long as the arrangement density of nano-wall-shaped semiconductor layer portions in the lateral direction is differentiated. In other words, the shape of the semiconductor layer itself and the arrangement interval are not necessarily limited as long as the nano-structure 30 includes the first regions R1 in which the proportion of the semiconductor layers is relatively high and the transmission loss of light is low and the second regions R2 in which the proportion of the insulator having a low refractive index is relatively high and the reflection loss of light is low.

FIG. 8 shows the calculation result of the light absorption amount of the photovoltaic device according to one aspect of this embodiment. In the graph shown in FIG. 8, the light absorption (dotted line) in a comparative structure in which silicon nano-walls are uniformly arranged and the light absorption (solid line) of the structure according to this embodiment in which silicon nano-walls are nonuniformly arranged are calculated by a finite-difference time-domain (FDTD) method.

The uniform arrangement structure is a structure in which silicon nano-walls having a thickness T of 10 nm in the arrangement direction X are uniformly arranged at a pitch P of 20 nm. The nonuniform arrangement structure is a structure in which the above-described high-density first regions R1 and the above-described low-density second regions R2 are periodically formed as illustrated in FIG. 1. In the high-density first regions R1, a plurality of silicon nano-walls having a thickness T of 10 nm in the arrangement direction X are formed at a pitch P of 20 nm. In the low-density second regions R2, insulating regions having a width of 150 nm where silicon nano-walls are not present are formed at intervals of 400 nm. As is clear from the graph shown in FIG. 8, the light absorption in the photovoltaic portion increases in the structure according to this embodiment in which the density of the nano-structure 30 is differentiated.

In FIG. 1, the case where the semiconductor layers in the nano-structure 30 have a nano-wall shape has been described as an example. The same applies to the case where the semiconductor layers have a nano-wire shape. FIG. 10 is a top view illustrating a nano-structure of a photovoltaic device according to a modification of this embodiment.

A nano-structure 40 in a photovoltaic device 110 includes nano-wire-shaped semiconductor layer portions formed so as to extend in a direction perpendicular to the light-receiving surface. The length d (diameter in the case where the nano-wires have a cylindrical shape) of a side of each nano-wire in the nano-structure 40 can be decreased to the degree that an increase in the forbidden band width is caused due to a quantum size effect. Specifically, the length of a side or the diameter of each nano-wire may be, for example, 10 nm or less, 6 nm or less, or about 4 nm.

The nano-structure 40 illustrated in FIG. 10 includes first regions R1′ in which nano-wire-shaped semiconductor layer portions are arranged at a first density (high density) and second regions R2′ in which nano-wire-shaped semiconductor layer portions are arranged at a second density (low density) which is different from the first density. Also in this case, both a low reflection loss and a low transmission loss can be achieved as in the case of the photovoltaic device 100. The conversion efficiency (i.e. generation efficiency) can be improved compared with nano-structure photovoltaic devices of the related art.

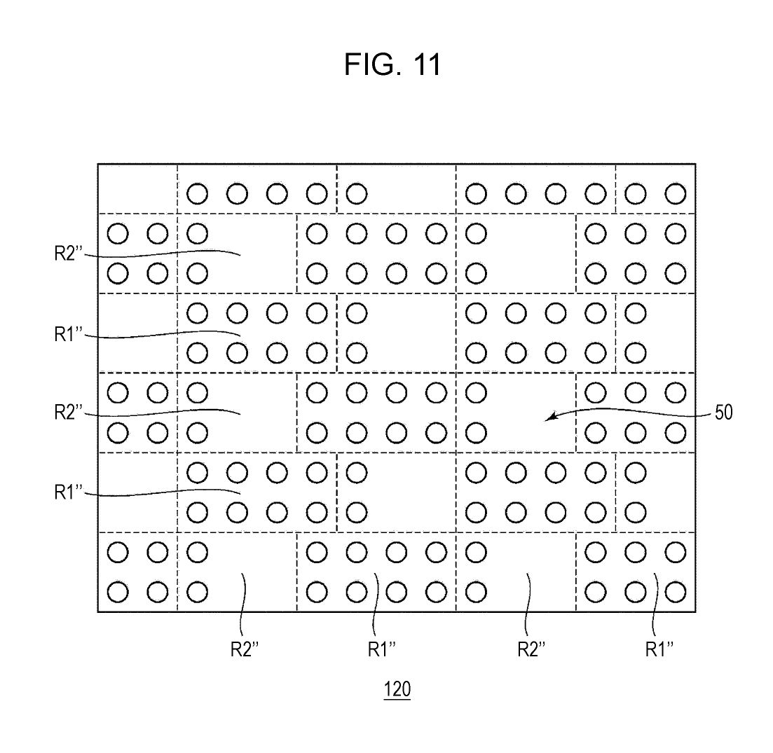

FIG. 11 is a top view illustrating a nano-structure of a photovoltaic device according to another modification of this embodiment. A nano-structure 50 in a photovoltaic device 120 includes, as in the nano-structure 40, nano-wire-shaped semiconductor layer portions formed so as to extend in a direction perpendicular to the light-receiving surface.

As illustrated in FIG. 11, the nano-structure 50 includes first regions R1″ in which nano-wire-shaped semiconductor layer portions are arranged at a first density (high density) and second regions R2″ in which nano-wire-shaped semiconductor layer portions are arranged at a second density (low density) which is different from the first density. In the nano-structure 50, the first regions R1″ and the second regions R2″ are periodically arranged in two intersecting directions which are horizontal to the first supporting substrate 10 (refer to FIG. 1). Thus, both a lower reflection loss and a lower transmission loss can be achieved.

The present disclosure has been described with reference to the above-described embodiments, but the present disclosure is not limited to the above-described embodiments and includes the structures of the embodiments that are suitably combined or replaced with each other. Furthermore, the combination and the order of processes in the embodiments can be suitably changed on the basis of the knowledge of those skilled in the art, and modifications such as various design changes can be added to the embodiments. The present disclosure also includes the embodiments to which such modifications are added.

The present disclosure includes the following embodiments.

A photovoltaic device comprising a photovoltaic portion having light-receiving surface that receives light, the photovoltaic portion including a nano-structure, wherein the nano-structure includes one or more first regions and one or more second regions, in each of the one or more first regions, semiconductor layer portions are arranged at a first density, in each of the one or more second regions, at least one semiconductor layer portion is arranged at a second density lower than the first density, and the nano-structure includes an insulator having a refractive index lower than refractive indices of the semiconductor layer portions arranged in the one or more first regions and the one or more second regions.

Thus, both a low reflection loss and a low transmission loss can be achieved.

For example, in the photovoltaic device according to the above embodiment, the one or more first regions are a plurality of the first regions, the one or more second regions are a plurality of the second regions, and in the nano-structure, the plurality of the first regions and the plurality of the seconds region are periodically arranged.

For example, in the photovoltaic device according to the above embodiment,

each of the semiconductor layer portions arranged in the one or more first regions and the one or more second regions has an incident surface on the light-receiving surface side, and a diameter or a shortest side of the incident surface is 10 nm or less.

Thus, the forbidden band width is increased due to a quantum size effect in the semiconductor layers, and the conversion efficiency of the photovoltaic device is improved.

For example, in the photovoltaic device according to the above embodiment, each of the semiconductor layer portions arranged in the one or more first regions and the one or more second regions has a nano-wall shape or a nano-wire shape.

What is claimed is:

1. A photovoltaic device comprising a photovoltaic portion having light-receiving surface that receives light, the photovoltaic portion including a nano-structure,
wherein the nano-structure includes one or more first regions and one or more second regions,
in each of the one or more first regions, semiconductor layer portions are arranged at a first density,
in each of the one or more second regions, at least one semiconductor layer portion is arranged at a second density lower than the first density, and the nano-structure includes an insulator having a refractive index lower than refractive indices of the semiconductor layer portions arranged in the one or more first regions and the one or more second regions.

2. The photovoltaic device according to claim 1, wherein the one or more first regions are a plurality of the first regions, the one or more second regions are a plurality of the second regions, and in the nano-structure, the plurality of the first regions and the plurality of the seconds region are periodically arranged.

3. The photovoltaic device according to claim 1, wherein each of the semiconductor layer portions arranged in the one or more first regions and the one or more second regions has an incident surface on the light-receiving surface side, and a diameter or a shortest side of the incident surface is 10 nm or less.

4. The photovoltaic device according to claim 1, wherein each of the semiconductor layer portions arranged in the one or more first regions and the one or more second regions has a nano-wall shape or a nano-wire shape.

5. The photovoltaic device according to claim 1, wherein the insulator is disposed to fill spaces in the nano-structure.
